(19) United States
(12) Patent Application Publication
(10) Pub. No.: US 2004/0092086 A1
(43) Pub. Date: May 13, 2004

(54) Film forming method and film forming device

(76) Inventors: Hitoshi Sakamoto, Hyogo (JP); Noriaki Ueda, Hyogo (JP); Takashi Sugino, Osaka (JP)

Correspondence Address: BIRCH STEWART KOLASCH & BIRCH, PO BOX 747, FALLS CHURCH, VA, 22040-0747, US

(21) Appl. No.: 10/472,449

(22) PCT Filed: Mar. 28, 2002
(86) PCT No.: PCT/JP02/03072

(30) Foreign Application Priority Data
Mar. 28, 2001 (JP) 2001-93500

(51) Int. Cl. C30B 1/00

(52) U.S. Cl. 438/485

(57) ABSTRACT

A plasma 10 is generated within a film formation chamber 2, and mainly a nitrogen gas 11 is excited within the film formation chamber 2. Then, the excited nitrogen gas 11 is mixed with a diborane gas 13 diluted with a hydrogen gas, and evaporated carbon obtained by controlled heating of a winding-shaped carbon heater 14a, to react them, thereby forming a boron carbonitride film 15 on a substrate 4. Thus, the boron carbonitride film 15 excellent in moisture absorption resistance, excellent in mechanical and chemical resistance, high in thermal conductivity, and having a low relative dielectric constant κ can be formed stably with good adhesion, and speedily over a uniform large area, regardless of the type of the film.

### TECHNICAL FIELD

This invention relates to a film forming method and a film forming apparatus for forming a boron carbonitride film.

### BACKGROUND ART

In an integrated circuit, a silicon dioxide film (SiO₂ film) by the plasma CVD (chemical vapor deposition) method has so far been used as an interlayer dielectric film. However, because of high integration of transistors and speeding of a switching action, losses due to capacitance between wirings have posed problems. To eliminate these losses, it is necessary to decrease the relative dielectric constant of the interlayer dielectric film, so that an interlayer dielectric film with a lower relative dielectric constant has been demanded. Under these circumstances, films of organic materials (for example, organosilicon films or films of amorphous carbon incorporating fluorine) can be provided with a very low relative dielectric constant (relative dielectric constant κ=2.5 or less), but these films have been problematical in mechanical and chemical resistance and thermal conductivity. Adhesion of the films has also presented a problem, and their moisture absorption resistance has been a problem in terms of density.

Under these circumstances, boron carbonitride (BNC), which is excellent in heat resistance and has a very low relative dielectric constant (relative dielectric constant κ=2.5 or less), is attracting attention. However, techniques for forming a BNC film by the plasma CVD (chemical vapor deposition) method have not been established, and the advent of a film forming method and a film forming apparatus capable of forming a BNC film as a product is in eager demand.

The present invention has been accomplished in view of the above situations, and its object is to provide a film forming method and a film forming apparatus which can form a film of boron carbonitride.

### DISCLOSURE OF THE INVENTION

The film forming method of the present invention is characterized by generating a plasma within a film formation chamber, exciting mainly a nitrogen gas within the film formation chamber, and then mixing the excited nitrogen gas with a diborane gas diluted with a hydrogen gas, and evaporated carbon, to react them, thereby forming a boron carbonitride film on a substrate.

Because of this feature, a boron carbonitride film excellent in moisture absorption resistance, excellent in mechanical and chemical resistance, high in thermal conductivity, and having a low relative dielectric constant κ can be formed stably with good adhesion, and speedily over a uniform large area, regardless of the type of the film.

The film forming method of the present invention is characterized by generating a plasma within a film formation chamber, exciting mainly a nitrogen gas within the film formation chamber, and then mixing the excited nitrogen gas with a diborane gas diluted with a hydrogen gas, and an organic gas vaporized upon heating, to react them, thereby forming a boron carbonitride film on a substrate.

Because of this feature, a boron carbonitride film excellent in moisture absorption resistance, excellent in mechanical and chemical resistance, high in thermal conductivity, and having a low relative dielectric constant κ can be formed stably with good adhesion, and speedily over a uniform large area, regardless of the type of the film.

The film forming method of the present invention is also characterized in that (nitrogen gas/diborane), the ratio between the flow rate of the nitrogen gas and the flow rate of diborane, is set at 0.1 to 10.0

The film forming method of the present invention is also characterized in that the (nitrogen gas/diborane) is set at 0.2 to 1.2.

The film forming method of the present invention is also characterized in that (organic gas/diborane), the ratio between the flow rate of the organic gas and the flow rate of diborane, is set at 0.01 to 1.0.

The film forming method of the present invention is characterized by generating a plasma within a film formation chamber, exciting mainly a nitrogen gas within the film formation chamber, and then mixing the excited nitrogen gas with a boron chloride gas using a hydrogen gas as a carrier gas, and evaporated carbon, to react them, thereby forming a boron carbonitride film on a substrate.

Because of this feature, a boron carbonitride film excellent in moisture absorption resistance, excellent in mechanical and chemical resistance, high in thermal conductivity, and having a low relative-dielectric constant κ can be formed safely with good adhesion, speedily over a uniform large area, and inexpensively with the use of starting materials easy to handle, regardless of the type of the film.

The film forming method of the present invention is characterized by generating a plasma within a film formation chamber, exciting mainly a nitrogen gas within the film formation chamber, and then mixing the excited nitrogen gas with a boron chloride gas using a hydrogen gas as a carrier gas, and an organic gas vaporized upon heating, to react them, thereby forming a boron carbonitride film on a substrate.

Because of this feature, a boron carbonitride film excellent in moisture absorption resistance, excellent in mechanical and chemical resistance, high in thermal conductivity, and having a low relative dielectric constant κ can be formed safely with good adhesion, speedily over a uniform large area, and inexpensively with the use of starting materials easy to handle, regardless of the type of the film.

The film forming method of the present invention is also characterized in that (nitrogen gas/boron chloride), the ratio between the flow rate of the nitrogen gas and the flow rate of the boron chloride gas, is set at 0.1 to 10.0

The film forming method of the present invention is also characterized in that the (nitrogen gas/boron chloride) is set at 0.7 to 1.3.

The film forming method of the present invention is also characterized in that (organic gas/boron chloride), the ratio between the flow rate of the organic gas and the flow rate of boron chloride, is set at 0.01 to 1.0.

The film forming method of the present invention is also characterized in that (hydrogen gas/boron chloride), the ratio between the flow rate of the hydrogen gas and the flow rate of the boron chloride, is set at 0.05 to 2.0.

The film forming method of the present invention is also characterized in that the plasma is generated by applying high frequency waves of 1 MHz to 100 MHz and 1 kW to 10 kW, and the temperature of the substrate is set at 200° C. to 400° C.

The film forming apparatus of the present invention is characterized by plasma generation means provided in an upper part of a film formation chamber for generating a plasma within the film formation chamber, a substrate holding portion provided in a lower part of the film formation chamber, nitrogen gas introduction means provided for introducing a nitrogen gas into the film formation chamber, and diborane gas introduction means provided for introducing a diborane gas diluted with a hydrogen gas, and evaporated carbon, to an interior of the film formation chamber below the nitrogen gas introduction means.

Because of this feature, a plasma is generated within a film formation chamber, mainly a nitrogen gas is excited within the film formation chamber, and then the excited nitrogen gas is mixed with a diborane gas diluted with a hydrogen gas, and evaporated carbon, to react them, thereby forming a boron carbonitride film on a substrate. As a result, a boron carbonitride film excellent in moisture absorption resistance, excellent in mechanical and chemical resistance, high in thermal conductivity, and having a low relative dielectric constant κ can be formed stably with good adhesion, and speedily over a uniform large area, regardless of the type of the film.

The film forming apparatus of the present invention is characterized by plasma generation means provided in an upper part of a film formation chamber for generating a plasma within the film formation chamber, a substrate holding portion provided in a lower part of the film formation chamber, nitrogen gas introduction means provided for introducing a nitrogen gas into the film formation chamber, and diborane gas introduction means provided for introducing a diborane gas diluted with a hydrogen gas, and an organic gas evaporated upon heating, to the interior of the film formation chamber below the nitrogen gas introduction means.

Because of this feature, a plasma is generated within a film formation chamber, mainly a nitrogen gas is excited within the film formation chamber, and then the excited nitrogen gas is mixed with a diborane gas diluted with a hydrogen gas, and an organic gas vaporized upon heating, to react them, thereby forming a boron carbonitride film on a substrate. As a result, a boron carbonitride film excellent in moisture absorption resistance, excellent in mechanical and chemical resistance, high in thermal conductivity, and having a low relative dielectric constant κ can be formed stably with good adhesion, and speedily over a uniform large area, regardless of the type of the film.

The film forming apparatus of the present invention is characterized by plasma generation means provided in an upper part of a film formation chamber for generating a plasma within the film formation chamber, a substrate holding portion provided in a lower part of the film formation chamber, nitrogen gas introduction means provided for introducing a nitrogen gas into the film formation chamber, and boron chloride gas introduction means provided for introducing a boron chloride gas using a hydrogen gas as a carrier gas, and evaporated carbon, to the interior of the film formation chamber below the nitrogen gas introduction means.

Because of this feature, a plasma is generated within a film formation chamber, mainly a nitrogen gas is excited within the film formation chamber, and then the excited nitrogen gas is mixed with a boron chloride gas using a hydrogen gas as a carrier gas, and evaporated carbon, to react them, thereby forming a boron carbonitride film on a substrate. As a result, a boron carbonitride film excellent in moisture absorption resistance, excellent in mechanical and chemical resistance, high in thermal conductivity, and having a low relative dielectric constant κ can be formed safely with good adhesion, speedily over a uniform large area, and inexpensively with the use of starting materials easy to handle, regardless of the type of the film.

The film forming apparatus of the present invention is characterized by plasma generation means provided in an upper part of a film formation chamber for generating a plasma within the film formation chamber, a substrate holding portion provided in a lower part of the film formation chamber, nitrogen gas introduction means provided for introducing a nitrogen gas into the film formation chamber, and boron chloride gas introduction means provided for introducing a boron chloride gas using a hydrogen gas as a carrier gas, and an organic gas evaporated upon heating, to the interior of the film formation chamber below the nitrogen gas introduction means.

Because of this feature, a plasma is generated within a film formation chamber, mainly a nitrogen gas is excited within the film formation chamber, and then the excited nitrogen gas is mixed with a boron chloride gas using a hydrogen gas as a carrier gas, and an organic gas vaporized upon heating, to react them, thereby forming a boron carbonitride film on a substrate. As a result, a boron carbonitride film excellent in moisture absorption resistance, excellent in mechanical and chemical resistance, high in thermal conductivity, and having a low relative dielectric constant κ can be formed safely with good adhesion, speedily over a uniform large area, and inexpensively with the use of starting materials easy to handle, regardless of the type of the film.

### BRIEF DESCRIPTION OF THE DRAWINGS

FIG. 1 is a schematic side view of a plasma CVD apparatus as a film forming apparatus for performing a film forming method according to a first embodiment of the present invention.

FIG. 2 is a graph representing the relationship between the ratio of diborane to nitrogen and the relative dielectric constant.

FIG. 3 is a schematic side view of a plasma CVD apparatus as a film forming apparatus for performing a film forming method according to a second embodiment of the present invention.

FIG. 4 is a graph illustrating the effect of tetraethoxysilane on moisture absorption properties.

FIG. 5 is a schematic side view of a plasma CVD apparatus as a film forming apparatus for performing a film forming method according to a third embodiment of the present invention.

FIG. 6 is a graph representing the relationship between the ratio of boron chloride to nitrogen and the relative dielectric constant.

FIG. 7 is a schematic side view of a plasma CVD apparatus as a film forming apparatus for performing a film forming method according to a fourth embodiment of the present invention.

FIG. 8 is a graph illustrating the effect of tetraethoxysilane on moisture absorption properties.

FIG. 9 is a schematic construction drawing of an integrated circuit in which film formation was performed by the film forming method using the plasma CVD apparatus of the present invention.

### BEST MODE FOR CARRYING OUT THE INVENTION

To describe the present invention in more detail, the invention will be illustrated in accordance with the accompanying drawings.

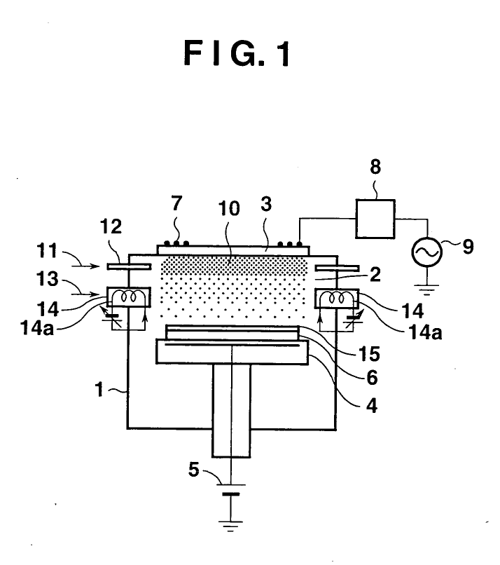

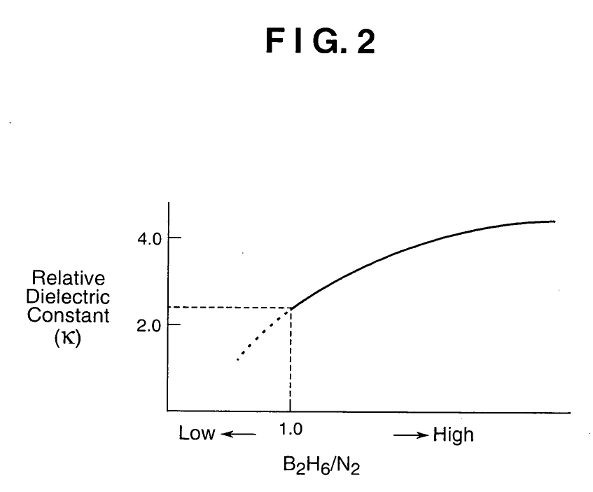

The first embodiment is explained based on FIGS. 1 and 2. FIG. 1 schematically shows a side view of a plasma CVD apparatus as a film forming apparatus for performing the film forming method according to the first embodiment of the present invention. FIG. 2 shows a graph representing the relationship between the ratio of diborane to nitrogen and the relative dielectric constant.

As shown in FIG. 1, a film formation chamber 2 is formed within a cylindrical container 1, and a circular ceiling board 3 is provided in an upper part of the container 1. An electrostatic chuck 4, as a substrate holding portion, is provided in the film formation chamber 2 at the center of the container 1. A direct current power source 5 for the electrostatic chuck is connected to the electrostatic chuck 4 so that a substrate 6 of a semiconductor (for example, a silicon wafer with a diameter of 300 mm or more) is electrostatically attracted thereto and held thereon.

A high frequency antenna 7 of a circular ring shape, for example, is disposed on the ceiling board 3, and a high frequency power source 9 is connected to the high frequency antenna 7 via a matching instrument 8. By supplying an electric power to the high frequency antenna 7, electromagnetic waves are shot into the film formation chamber 2 of the container 1. The electromagnetic waves shot into the container 1 ionize a gas within the film formation chamber 2 to generate a plasma 10 (plasma generation means).

The container 1 is provided with nitrogen gas nozzles 12, as nitrogen gas introduction means, for introducing a nitrogen gas (N₂ gas) 11 (>99.999%) into the film formation chamber 2. Diborane gas nozzles 14, as diborane gas introduction means, are provided for introducing a diborane(B₂H₆)-containing gas 13 to the interior of the film formation chamber 2 below the nitrogen gas nozzles 12. The B₂H₆-containing gas 13 introduced into the film formation chamber 2 through the diborane gas nozzles 14 is a B₂H₆ gas (1% to 5%) diluted with a hydrogen (H₂) gas. A winding-shaped carbon heater 14a is installed within the diborane gas nozzle 14, and the winding-shaped carbon heater 14a is temperature-controlled within the range of 1,000° C. to 3,000° C. by electric current control, whereby the amount of carbon evaporated is adjusted.

With the above-described plasma CVD apparatus, the substrate 6 is placed on the electrostatic chuck 4 and electrostatically attracted thereto. The N₂ gas 11 is introduced at a predetermined flow rate through the nitrogen gas nozzle 12, while the B₂H₆-containing gas 13 is introduced at a predetermined flow rate through the diborane gas nozzle 14 equipped with the winding-shaped carbon heater 14a. Heating of the winding-shaped carbon heater 14a results in the evaporation of solid-phase carbon. An electric power is supplied from the high frequency power source 9 to the high frequency antenna 7 to apply high frequency waves (1 MHz to 100 MHz, 1 kW to 10 kW) via the matching instrument 8. As a result, mainly the N₂ gas 11 is excited within the film formation chamber 2 to change into a plasma state. After the N₂ gas 11 is excited, it is mixed with the B₂H₆-containing gas 13 and an evaporated gas from the solid carbon source and reacted thereby, whereby a boron carbonitride (BNC) film 15 is formed on the substrate 6, with the amount of evaporated carbon being controlled by temperature control of the winding-shaped carbon heater 14a. At this time, the temperature of the substrate 6 is set at 200° C. to 400° C.

The resulting BNC film 15 was measured for voltage-capacitance, and the relative dielectric constant κ of the film was confirmed to be κ=2.2 to 2.6.

Within the film formation chamber 2, the nitrogen gas nozzle 12 is provided beside the high frequency antenna 7. Thus, mainly the N₂ gas 11 is excited and converted into a plasma gas. The plasma gas, the B₂H₆ gas diluted with H₂ gas, and the evaporated carbon are reacted. When the B₂H₆ gas passes through the heated winding-shaped carbon heater 14a, the atomic hydrogen is eliminated, and binds to carbon through a reduction reaction to form a hydrocarbon-based substance, which vaporizes as evaporated carbon. Alternatively, when the B₂H₆ gas passes through the heated winding-shaped carbon heater 14a, it directly turns into a boron carbide-based substance. Through this reaction, BNC and H₂ gas or ammonia are formed. The H₂ gas or ammonia is discharged to the outside, and the BNC film 15 is formed on the substrate 6. If the diborane gas nozzle 14 is disposed beside the high frequency antenna 7 to convert the B₂H₆-containing gas 13 into a plasma, boron solidifies and becomes unreactive with nitrogen.

The range of the flow rate of the N₂ gas 11 from the nitrogen gas nozzle 12 and the flow rate of the B₂H₆-containing gas 13 from the diborane gas nozzle 14 is set such that (N₂ gas/B₂H₆), the ratio of the flow rate of the N₂ gas to the flow rate of B₂H₆, is 0.1 to 10.0. Preferably, the range is set such that (N₂ gas/B₂H₆) is 0.2 to 1.2. More preferably, the range is set such that (N₂ gas/B₂H₆) is 1.0.

As shown in FIG. 2, if the value of B₂H₆/N₂ is large (if the flow rate of the N₂ gas is low) with the film thickness being constant, the relative dielectric constant κ is high, and when the value of B₂H₆/N₂ is 1.0, the relative dielectric constant κ is 2.2. Thus, the BNC film 15 having a very low relative dielectric constant κ of κ=2.2 to 2.6 is formed by setting the flow rate of the N₂ gas 11 and the flow rate of the B₂H₆-containing gas 13 such that N₂ gas/B₂H₆ is 0.1 to 10.0 (preferably, 0.2 to 1.2, further 1.0). If the flow rate of the N₂ gas 11 is low, boron solidifies. If the flow rate of the N₂ gas 11 is high, no film is deposited.

With the film forming method using the plasma CVD apparatus described above, the BNC film 15 excellent in moisture absorption resistance, excellent in mechanical and chemical resistance, high in thermal conductivity, and having a low relative dielectric constant κ(κ=2.2 to 2.6) can be formed stably with good adhesion, and over a uniform large area, regardless of the type of the film. The use of B₂H₆ permits speedy film formation.

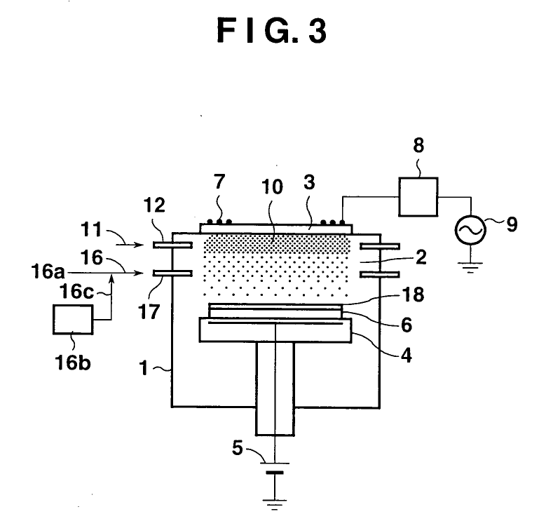

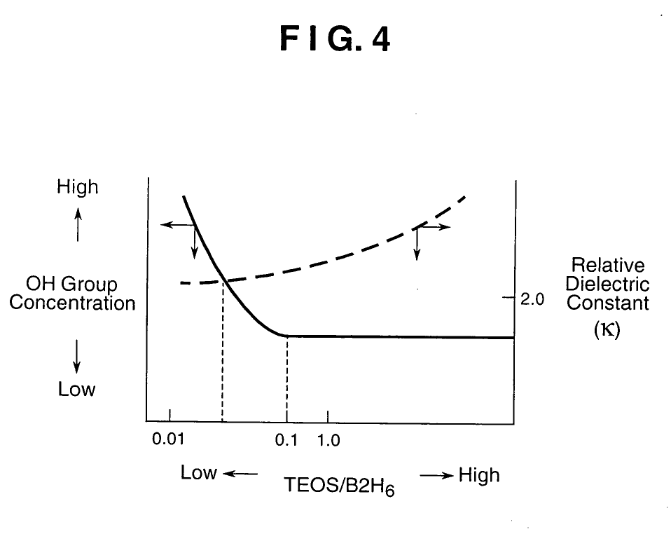

The second embodiment will be described based on FIGS. 3 and 4. FIG. 3 is a schematic side view of a plasma CVD apparatus as a film forming apparatus for performing the film forming method according to the second embodiment of the present invention. FIG. 4 shows a graph illustrating the effect of tetraethoxysilane on moisture absorption properties. The same members as the members shown in FIG. 1 are assigned the same numerals, and duplicate explanations are omitted.

The container 1 is provided with nitrogen gas nozzles 12 for introducing a nitrogen gas (N₂ gas) 11 (>99.999%) into the film formation chamber 2. Mixed gas nozzles 17, as diborane gas introduction means, are provided for introducing a diborane(B₂H₆)-containing gas and a tetraethoxysilane (Si(O—C₂H₅)₄; hereinafter referred to as TEOS) gas, as an organic gas, i.e., (B₂H₆-containing gas +TEOS gas) 16, to the interior of the film formation chamber 2 below the nitrogen gas nozzles 12. The (B₂H₆-containing gas+TEOS gas) 16 is obtained by the mixing of a TEOS gas 16c, which has been evaporated upon heating at 50° C. to 100° C. within a liquid container 16b, with a B₂H₆-containing gas 16a. The B₂H₆-containing gas 16a is a B₂H₆ gas (1% to 5%) diluted with a hydrogen (H₂) gas.

Ethanol, acetone, methanol or butanol can be employed as the organic gas.

With the above-described plasma CVD apparatus, the N₂ gas 11 is introduced at a predetermined flow rate through the nitrogen gas nozzle 12, while the (B₂H₆-containing gas +TEOS gas) 16 is introduced at a predetermined flow rate through the mixed gas nozzle 17. An electric power is supplied from the high frequency power source 9 to the high frequency antenna 7 to apply high frequency waves (1 MHz to 100 MHz, 1 kW to 10 kW) via the matching instrument 8. As a result, mainly the N₂ gas 11 is excited within the film formation chamber 2 to change into a plasma state. After the N₂ gas 11 is excited, it is mixed with the (B₂H₆-containing gas+TEOS gas) 16 and reacted thereby, whereby a boron carbonitride (BNC) film 18 is formed on the substrate 6. At this time, the temperature of the substrate 6 is set at 200° C. to 400° C.

The resulting BNC film 18 was measured for voltage-capacitance, and the relative dielectric constant κ of the film was confirmed to be κ=2.2 to 2.6.

Within the film formation chamber 2, the nitrogen gas nozzle 12 is provided beside the high frequency antenna 7. Thus, mainly the N₂ gas 11 is excited and converted into a plasma gas. The plasma gas reacts with the (B₂H₆-containing gas+TEOS gas) 16. Through this reaction, BN and H₂ gas or ammonia are formed, and the ethyl groups of the TEOS gas are taken up. Consequently, some of the N atoms of BN, a hexagonal crystal structure, are substituted by carbon atoms (C) to form BNC. The H₂ gas or ammonia is discharged to the outside, and the BNC film 18 is formed on the substrate 6.

The range of the flow rate of the N₂ gas 11 from the nitrogen gas nozzle 12 and the flow rate of the B₂H₆-containing gas of the (B₂H₆containing gas+TEOS gas) 16 from the mixed gas nozzle 17 is set such that (N₂ gas/B₂H₆), the ratio of the flow rate of the N₂ gas to the flow rate of B₂H₆, is 0.1 to 10.0. Preferably, the range is set such that (N₂ gas/B₂H₆) is 0.2 to 1.2. More preferably, the range is set such that (N₂ gas/B₂H₆) is 1.0.

Moreover, the ranges of the flow rates of the B₂H₆-containing gas and the TEOS gas of the (B₂H₆-containing gas+TEOS gas) 16 from the mixed gas nozzle 17 are set such that (TEOS/B₂H₆), i.e., (organic gas/diborane) which is the ratio of the flow rate of TEOS to the flow rate of B₂H₆, is 0.01 to 1.0.

As indicated by a solid line in FIG. 4, it is shown, because of the properties of the BNC film, that if the value of TEOS/B₂H₆ increases, say, up to about 0.1, with the film thickness being constant, the concentration of the hydroxyl groups (OH groups) gradually decreases, meaning no moisture absorption (excellent moisture absorption resistance). As indicated by a dashed line in FIG. 4, on the other hand, when the value of TEOS/B₂H₆ becomes large, the relative dielectric constant κ is high. Thus, the BNC film 18 excellent in moisture absorption resistance and having a low relative dielectric constant κ is obtained by setting TEOS/B₂H₆ at 0.01 to 1.0.

With the film forming method using the plasma CVD apparatus described above, the BNC film 18 excellent in moisture absorption resistance, excellent in mechanical and chemical resistance, high in thermal conductivity, and having a low relative dielectric constant κ (κ=2.2 to 2.6) can be formed stably with good adhesion, and over a uniform large area, regardless of the type of the film. The use of B₂H₆ permits speedy film formation.

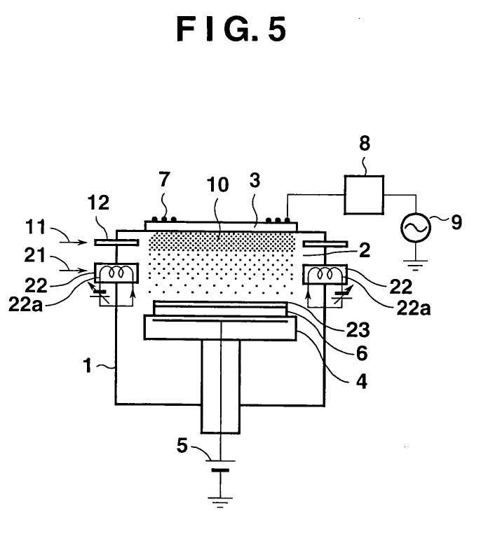

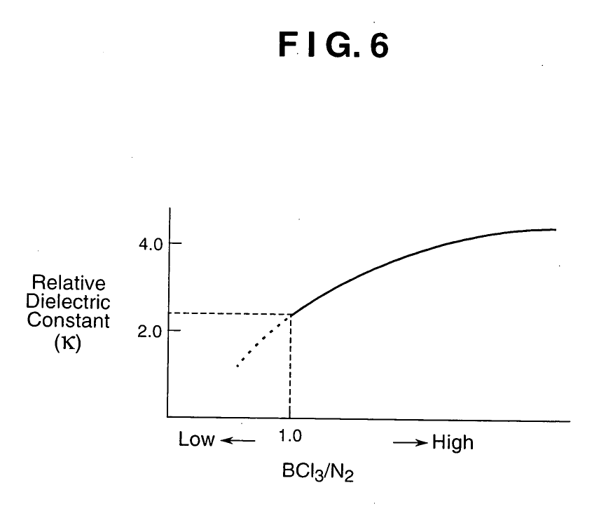

The third embodiment will be described based on FIGS. 5 and 6. FIG. 5 is a schematic side view of a plasma CVD apparatus as a film forming apparatus for performing the film forming method according to the third embodiment of the present invention. FIG. 6 is a graph representing the relationship between the ratio of boron chloride to nitrogen and the relative dielectric constant. The same members as the members shown in FIG. 1 are assigned the same numerals, and duplicate explanations are omitted.

The container 1 is provided with nitrogen gas nozzles 12 for introducing a nitrogen gas (N₂ gas) 11 (>99.999%) into the film formation chamber 2. Boron chloride gas nozzles 22, as boron chloride gas introduction means, are provided for introducing a boron chloride (BCl₃: >99.999%) gas 21 using a hydrogen (H₂) gas as a carrier gas to the interior of the film formation chamber 2 below the nitrogen gas nozzles 12. A winding-shaped carbon heater 22a is installed within the boron chloride gas nozzle 22, and the winding-shaped carbon heater 22a is temperature-controlled within the range of 1,000° C. to 3,000° C. by electric current control, whereby the amount of carbon evaporated is adjusted.

With the above-described plasma CVD apparatus, the N₂ gas 11 is introduced at a predetermined flow rate through the nitrogen gas nozzle 12, while the BC1₃ gas 21 using an H₂ gas as a carrier gas is introduced at a predetermined flow rate through the boron chloride gas nozzle 22 equipped with the winding-shaped carbon heater 22a. Solid-phase carbon is evaporated by heating of the winding-shaped carbon heater 22a. An electric power is supplied from the high frequency power source 9 to the high frequency antenna 7 to apply high frequency waves (1 MHz to 100 MHz, 1 kW to 10 kW) via the matching instrument 8. As a result, mainly the N₂ gas 11 is excited within the film formation chamber 2 to change into a plasma state. After the N₂ gas 11 is excited, it is mixed with the BCl₃ gas 21 using an H₂ gas as a carrier gas and the evaporated gas from the solid-phase carbon source, and reacted thereby, whereby a boron carbonitride (BNC) film 23 is formed on the substrate 6, with the amount of the evaporated carbon being controlled by the temperature control of the winding-shaped carbon heater 22a. At this time, the temperature of the substrate 6 is set at 200° C. to 400° C.

The resulting BNC film 23 was measured for voltage-capacitance, and the relative dielectric constant κof the film was confirmed to be κ=2.2 to 2.6.

Within the film formation chamber 2, the nitrogen gas nozzle 12 is provided beside the high frequency antenna 7. Thus, mainly the N₂ gas 11 is excited and converted into a plasma gas. The plasma gas, the BCl₃ gas 21 using an H₂ gas as a carrier gas, and the evaporated carbon are reacted. Through this reaction, chlorine is eliminated during a reduction reaction, and boron and carbonitride are reacted to form BNC and HCL gas. The HCl gas is discharged to the outside, and the BNC film 23 is formed on the substrate 6.

The range of the flow rate of the N₂ gas 11 from the nitrogen gas nozzle 12 and the flow rate of the BCl₃ gas 21 using an H₂ gas as a carrier gas from the boron chloride gas nozzle 22 is set such that (N₂ gas/BCl₃), the ratio of the flow rate of the N₂ gas to the flow rate of BCl₃, is 0.1 to 10.0. Preferably, the range is set such that (N₂ gas/BCl₃) is 0.7 to 1.3. More preferably, the range is set such that (N₂ gas/BCl₃) is 1.0.

Moreover, the ranges of the flow rates of an H₂ gas and BCl₃ of the BCl₃ gas 21 using an H₂ gas as a carrier gas through the boron chloride gas nozzle 22 are set such that H₂ gas/BCl₃ which is the ratio of the H₂ gas to BCl₃, is 0.05to 2.0.

As shown in FIG. 6, if the value of BCl₃/N₂ is large (if the flow rate of the N₂ gas is low) with the film thickness being constant, the relative dielectric constant κ is high, and when the value of BCl₃/N₂ is 1.0, the relative dielectric constant κ is 2.2. Thus, the BNC film 23 having a very low relative dielectric constant κ of κ=2.2 to 2.6 is formed by setting the flow rate of the N₂ gas 11 and the flow rate of the BCl₃ gas 21 using an H₂ gas as a carrier gas such that N₂ gas/BCl₃ is 0.1 to 10.0 (preferably, 0.7 to 1.3, further 1.0).

With the film forming method using the plasma CVD apparatus described above, the BN film 23 excellent in moisture absorption resistance, excellent in mechanical and chemical resistance, high in thermal conductivity, and having a low relative dielectric constant κ (κ=2.2 to 2.6) can be formed safely with good adhesion, and over a uniform large area, regardless of the type of the film. The use of liquid BCl₃ makes it possible to form the BNC film 23 stably from starting materials which are inexpensive and easy to handle.

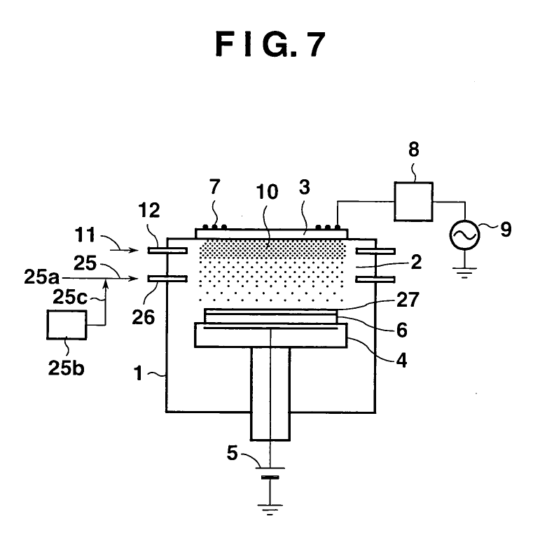

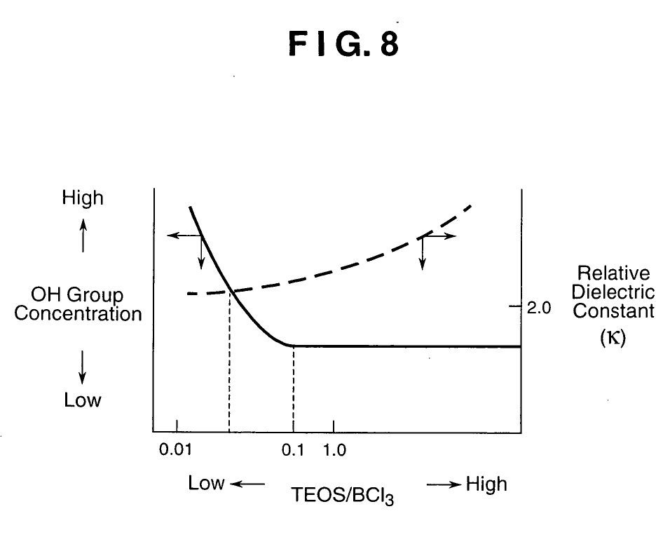

The fourth embodiment will be described based on FIGS. 7 and 8. FIG. 7 is a schematic side view of a plasma CVD apparatus as a film forming apparatus for performing the film forming method according to the fourth embodiment of the present invention. FIG. 8 shows a graph illustrating the effect of tetraethoxysilane on moisture absorption properties. The same members as the members shown in FIG. 1 are assigned the same numerals, and duplicate explanations are omitted.

The container 1 is provided with nitrogen gas nozzles 12 for introducing a nitrogen gas (N₂ gas) 11 (>99.999%) into the film formation chamber 2. Mixed gas nozzles 26, as boron chloride gas introduction means, are provided for introducing a BCl₃ gas using an H₂ gas as a carrier gas and a tetraethoxysilane (Si(O—C₂H₅)₄; hereinafter referred to as TEOS) gas, as an organic gas, i.e., (BCl₃ gas using an H₂ gas as a carrier gas+TEOS gas) 25, to the interior of the film formation chamber 2 below the nitrogen gas nozzles 12. The (BCl₃ gas using an H₂ gas as a carrier gas +TEOS gas) 25 is obtained by the mixing of a TEOS gas 25c, which has been evaporated upon heating at 50° C. to 100° C. within a liquid container 25b, with a B₂H₆-containing gas 25a. The B₂H₆-containing gas 25a is a B₂H₆ gas (1% to 5%) diluted with a hydrogen (H₂) gas.

Ethanol or acetone can be employed as the organic gas.

With the above-described plasma CVD apparatus, the N₂ gas 11 is introduced at a predetermined flow rate through the nitrogen gas nozzle 12, while the (BCl₃ gas using an H₂ gas as a carrier gas+TEOS gas) 25 is introduced at a predetermined flow rate through the mixed gas nozzle 26. An electric power is supplied from the high frequency power source 9 to the high frequency antenna 7 to apply high frequency waves (1 MHz to 100 MHz, 1 kW to 10 kW) via the matching instrument 8. As a result, mainly the N₂ gas 11 is excited within the film formation chamber 2 to change into a plasma state. After the N₂ gas 11 is excited, it is mixed with the (BCl₃ gas using an H₂ gas as a carrier gas+TEOS gas) 25 and reacted thereby, whereby a boron carbonitride (BNC) film 27 is formed on the substrate 6. At this time, the temperature of the substrate 6 is set at 200° C. to 400° C.

The resulting BNC film 27 was measured for voltage-capacitance, and the relative dielectric constant κof the film was confirmed to be κ=2.2 to 2.6.

Within the film formation chamber 2, the nitrogen gas nozzle 12 is provided beside the high frequency antenna 7. Thus, mainly the N₂ gas 11 is excited and converted into a plasma gas. The plasma gas reacts with the (BCl₃ gas using an H₂ gas as a carrier gas+TEOS gas) 25. Through this reaction, chlorine is eliminated during a reduction reaction, and boron and nitrogen are reacted to form BN and HCL gas. Moreover, the ethyl groups of the TEOS gas are taken up. Consequently, some of the N atoms of BN, a hexagonal crystal structure, are substituted by carbon atoms (C) to form BNC. The HCl gas is discharged to the outside, and the BNC film 27 is formed on the substrate 6.

The range of the flow rate of the N₂ gas 11 from the nitrogen gas nozzle 12 and the flow rate of BCl₃ of (BCl₃ gas using an H₂ gas as a carrier gas+TEOS gas) 25 from the mixed gas nozzle 26 is set such that (N₂ gas/BCl₃), the ratio of the flow rate of the N₂ gas to the flow rate of BCl₃, is 0.1 to 10.0. Preferably, the range is set such that (N₂ gas/BCl₃) is 0.7 to 1.3. More preferably, the range is set such that (N₂ gas/BCl₃) is 1.0.

Moreover, the ranges of the flow rates of the H₂ gas and BCl₃ of the (BCl₃ gas using an H₂ gas as a carrier gas+TEOS gas) 25 through the mixed gas nozzle 26 are set such that (H₂ gas/BCl₃) which is the ratio of the flow rate of the H₂ gas to the flow rate of BCl₃, is 0.05 to 2.0.

Furthermore, the ranges of the flow rates of BCl₃ and the TEOS gas of the (BCl₃ gas using an H₂ gas as a carrier gas+TEOS gas) 25 through the mixed gas nozzle 26 are set such that (TEOS/BCl₃) which is the ratio of the flow rates of TEOS and BCl₃ (organic gas/boron chloride) is 0.01 to 1.0.

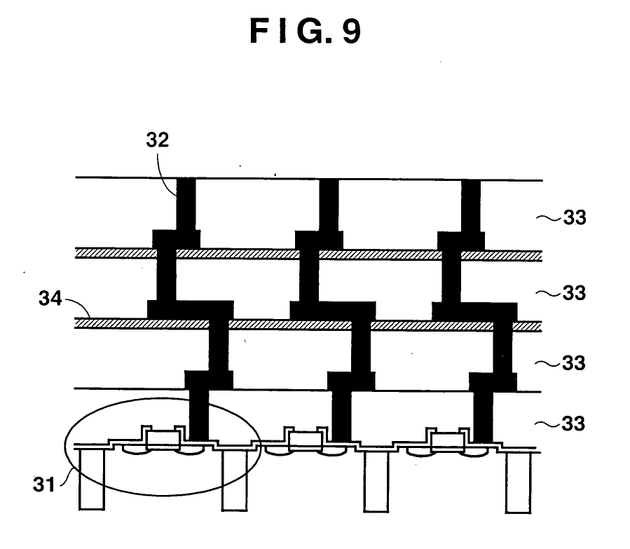

As indicated by a solid line in FIG. 8, it is shown, because of the properties of the BNC film, that if the value of TEOS/BCl₃ increases, say, up to about 0.1, with the film thickness being constant, the concentration of the hydroxyl groups (OH groups) gradually decreases, meaning no moisture absorption (excellent moisture absorption resistance). As indicated by a dashed line in FIG. 9, on the other hand, when the value of TEOS/BCl₃ becomes large, the relative dielectric constant κ is high. Thus, the BNC film 27 excellent in moisture absorption resistance and having a low relative dielectric constant κis obtained by setting TEOS/BCl₃ at 0.01 to 1.0.

With the film forming method using the plasma CVD apparatus described above, the BNC film 27 excellent in moisture absorption resistance, excellent in mechanical and chemical resistance, high in thermal conductivity, and having a low relative dielectric constant κ(κ=2.2 to 2.6) can be formed safely with good adhesion, and over a uniform large area, regardless of the type of the film. The use of liquid BCl₃ makes it possible to form the BN film 27 stably from materials which are inexpensive and easy to handle.

An example of the application of a BNC film, which can be formed by any of the film forming methods using the plasma CVD apparatuses in the above-described first to fourth embodiments, will be explained based on FIG. 9. FIG. 9 shows a schematic construction of an integrated circuit in which film formation was performed by the film forming method using the plasma CVD apparatus of the present invention.

In a highly integrated circuit (LSI), as shown in the drawing, losses due to capacitance between wirings 32 are eliminated to achieve high integration of transistors 31 and speeding of a switching action. Thus, a film with a low relative dielectric constant is used as an interlayer dielectric film 33 between the wirings 32 during the manufacturing process. An organic coated film or a porous film with a low relative dielectric constant is adopted as the interlayer dielectric film 33. Further, a BNC film is formed as a protective film 34 between the interlayer dielectric films 33 by the film forming method using the plasma CVD apparatus in any of the first to sixth embodiments.

The interlayer dielectric film 33, as an organic coated film or a porous film, has a low relative dielectric constant, but has been problematical in terms of mechanical and chemical resistance and thermal conductivity. Hence, a further film with a low relative dielectric constant is combined as the protective film 34 excellent in mechanical and chemical resistance, high in thermal conductivity and having a low relative dielectric constant. This combination makes it possible to fulfill the demand for the interlayer dielectric film 33 complying with the LSI process, which involves strict processing conditions, while maintaining adhesion and moisture absorption resistance.

The interlayer dielectric film 33, as an organic coated film or a porous film, and the protective film 34 were measured for voltage-capacitance, and the relative dielectric constant κ of <2.2 was confirmed to be obtained.

Industrial Applicability

As described above, the present invention provides the film forming method and the film forming apparatus which can form a boron carbonitride film excellent in moisture absorption resistance, excellent in mechanical and chemical resistance, high in thermal conductivity, and having a low relative dielectric constant κ can be formed stably with good adhesion, and speedily over a uniform large area, regardless of the type of the film.

1. A film forming method characterized by generating a plasma within a film formation chamber, exciting mainly a nitrogen gas within the film formation chamber, and then mixing the excited nitrogen gas with a diborane gas diluted with a hydrogen gas, and evaporated carbon, to react them, thereby forming a boron carbonitride film on a substrate.

2. A film forming method characterized by generating a plasma within a film formation chamber, exciting mainly a nitrogen gas within the film formation chamber, and then mixing the excited nitrogen gas with a diborane gas diluted with a hydrogen gas, and an organic gas vaporized upon heating, to react them, thereby forming a boron carbonitride film on a substrate.

3. The film forming method of claim 1 or 2, characterized in that (nitrogen gas/diborane), a ratio between a flow rate of the nitrogen gas and a flow rate of diborane, is set at 0.1 to 10.0.

4. The film forming method of claim 3, characterized in that the (nitrogen gas/diborane) is set at 0.2 to 1.2.

5. The film forming method of claim 2, characterized in that (organic gas/diborane), a ratio between a flow rate of the organic gas and a flow rate of diborane, is set at 0.01 to 1.0.

6. A film forming method characterized by generating a plasma within a film formation chamber, exciting mainly a nitrogen gas within the film formation chamber, and then mixing the excited nitrogen gas with a boron chloride gas using a hydrogen gas as a carrier gas, and evaporated carbon, to react them, thereby forming a boron carbonitride film on a substrate.

7. A film forming method characterized by generating a plasma within a film formation chamber, exciting mainly a nitrogen gas within the film formation chamber, and then mixing the excited nitrogen gas with a boron chloride gas using a hydrogen gas as a carrier gas, and an organic gas vaporized upon heating, to react them, thereby forming a boron carbonitride film on a substrate.

8. The film forming method of claim 6 or 7, characterized in that (nitrogen gas/boron chloride), a ratio between a flow rate of the nitrogen gas and a flow rate of the boron chloride gas, is set at 0.1 to 10.0.

9. The film forming method of claim 8, characterized in that the (nitrogen gas/boron chloride) is set at 0.7 to 1.3.

10. The film forming method of claim 7, characterized in that (organic gas/boron chloride), a ratio between a flow rate of the organic gas and a flow rate of boron chloride, is set at 0.01 to 1.0.

11. The film forming method of any one of claims 6, 7, 8, 9 and 10, characterized in that (hydrogen gas/boron chloride), a ratio between a flow rate of the hydrogen gas and a flow rate of boron chloride, is set at 0.05 to 2.0.

12. The film forming method of any one of claims 1 to 11, characterized in that the plasma is generated by applying high frequency waves of 1 MHz to 100 MHz and 1 kW to 10 kW, and a temperature of the substrate is set at 200° C. to 400° C.

13. A film forming apparatus characterized by:
plasma generation means provided in an upper part of a film formation chamber for generating a plasma within the film formation chamber;
a substrate holding portion provided in a lower part of the film formation chamber;
nitrogen gas introduction means provided for introducing a nitrogen gas into the film formation chamber; and
diborane gas introduction means provided for introducing a diborane gas diluted with a hydrogen gas, and evaporated carbon, to an interior of the film formation chamber below the nitrogen gas introduction means.

14. A film forming apparatus characterized by:
plasma generation means provided in an upper part of a film formation chamber for generating a plasma within the film formation chamber;
a substrate holding portion provided in a lower part of the film formation chamber;
nitrogen gas introduction means provided for introducing a nitrogen gas into the film formation chamber; and
diborane gas introduction means provided for introducing a diborane gas diluted with a hydrogen gas, and an organic gas evaporated upon heating, to an interior of the film formation chamber below the nitrogen gas introduction means.

15. A film forming apparatus characterized by:
plasma generation means provided in an upper part of a film formation chamber for generating a plasma within the film formation chamber;
a substrate holding portion provided in a lower part of the film formation chamber;
nitrogen gas introduction means provided for introducing a nitrogen gas into the film formation chamber; and
boron chloride gas introduction means provided for introducing a boron chloride gas using a hydrogen gas as a carrier gas, and evaporated carbon, to an interior of the film formation chamber below the nitrogen gas introduction means.

16. A film forming apparatus characterized by:
plasma generation means provided in an upper part of a film formation chamber for generating a plasma within the film formation chamber;
a substrate holding portion provided in a lower part of the film formation chamber;
nitrogen gas introduction means provided for introducing a nitrogen gas into the film formation chamber; and
boron chloride gas introduction means provided for introducing a boron chloride gas using a hydrogen gas as a carrier gas, and an organic gas evaporated upon heating, to an interior of the film formation chamber below the nitrogen gas introduction means.
